(19) United States
(12) Patent Application Publication
(10) Pub. No.: US 2015/0255748 A1
(43) Pub. Date: Sep. 10, 2015

(54) LOW PERMEATION GAS ULTRA-BARRIER WITH WET PASSIVATION LAYER

(71) Applicant: SAMSUNG SDI CO., LTD., Yongin-si (KR)

(72) Inventors: Damien Boesch, San Jose, CA (US); Lorenza Moro, Palo Alto, CA (US); Sina Maghsoodi, San Jose, CA (US)

(21) Appl. No.: 14/636,075

(22) Filed: Mar. 2, 2015

Related U.S. Application Data
(60) Provisional application No. 61/950,809, filed on Mar. 10, 2014.

(51) Int. Cl. H01L 51/52; C09D 183/04

(52) U.S. Cl. CPC H01L 51/5253; C09D 183/04

(57) ABSTRACT

Barrier stacks according to embodiments of the present invention achieve good water vapor transmission rates with a reduced number of dyads (i.e., polymer layer/oxide layer couple). In some embodiments, the barrier stack includes one or more dyads comprising a first polymer decoupling layer and a second barrier layer on the first layer. A passivation layer is wet deposited on the second layer of at least one of the dyads. The passivation layer includes a wet coated and cured curable material that seals the localized defects in the underlying barrier layer, and the barrier stack including the passivation layer has a water vapor transmission rate that is lower than a water vapor transmission rate of a barrier stack not including the passivation layer.

### CROSS-REFERENCE TO RELATED APPLICATION(S)

This application claims priority to and the benefit of U.S. Provisional Patent Application No. 61/950,809, filed on Mar. 10, 2014 and titled LOW PERMEATION GAS ULTRA-BARRIER WITH WET PASSIVATION LAYER, the entire content of which is incorporated herein by reference.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are typically coated with a barrier coating or are encapsulated by incorporating a barrier stack adjacent one or both sides of the device.

Barrier coatings typically include a single layer of inorganic material, such as aluminum, silicon or aluminum oxides, or silicon nitrides. However, for many devices, such a single layer barrier coating does not sufficiently reduce or prevent oxygen or water vapor permeability. Indeed, in organic light emitting devices, for example, which require exceedingly low oxygen and water vapor transmission rates, these single layer barrier coatings do not adequately reduce or prevent the permeability of damaging gases, liquids and chemicals. Accordingly, in those devices (e.g., organic light emitting devices and the like), barrier stacks have been used in an effort to further reduce or prevent the permeation of damaging gases, liquids and chemicals.

In general, a barrier stack includes multiple dyads, each dyad being a two-layered structure including a barrier layer and a decoupling layer. The barrier stack can be deposited directly on the device to be protected, or may be deposited on a separate film or support, and then laminated onto the device. The decoupling layer(s) and barrier layer(s) can be deposited by any of various techniques (e.g., vacuum deposition processes or atmospheric processes), but the deposition of suitably dense layers with appropriate barrier properties is typically achieved by supplying energy to the material that will ultimately form the layer. The energy supplied to the material can be thermal energy, but in many deposition processes, ionization radiation is used to increase the ion production in the plasma and/or to increase the number of ions in the evaporated material streams. The produced ions are then accelerated toward the substrate either by applying a DC or AC bias to the substrate, or by building up a potential difference between the plasma and the substrate.

For example, low energy plasma can be used to deposit the oxides of a barrier layer. However, a layer deposited using such low energy plasma has surface defects and low density, providing limited protection of the encapsulated device (e.g., an organic light emitting device) from the permeation of damaging gases, liquids, and chemicals. A common solution to this problem has been to provide multiple dyads (i.e., multiple stacks of the decoupling and barrier layers) in order to provide an effective barrier stack (or ultrabarrier). However, such a practice increases the cost and time of manufacture.

### SUMMARY

According to some embodiments of the present invention, a barrier stack includes one or more dyads, where each dyad includes a first layer comprising a polymer or organic material, and a second layer on the first layer and comprising a barrier material. The barrier stack further includes a passivation layer on the second layer of at least one of the dyads, and the passivation layer includes a wet coated and cured curable material. The barrier stack including the passivation layer has a water vapor transmission rate that is lower than a water vapor transmission rate of a barrier stack comprising the dyads but not including the passivation layer. In some embodiments, the barrier stack may further include a fourth layer between a substrate or device and the first layer.

The polymer or organic material of the first layer may be selected from organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof. The barrier material of the second layer may be selected from metals, metal oxides, metal nitrides, metal oxynitrides, metal carbides, metal oxyborides, Al, Zr, Zn, Sn, Ti, and combinations thereof.

The curable material of the passivation layer may include a liquid polymer solution, an inorganic slurry composition, or a hybrid system comprising an inorganic material and a liquid polymer solution. The liquid polymer solution may include an organopolysiloxane polymer and a solvent. For example, the liquid polymer solution may include a water borne polysiloxane polymer prepared by a sol-gel process, and a solvent. The inorganic slurry composition may include an inorganic oxide dispersed in a solvent.

In some embodiments, a method of making a barrier stack includes forming one or more dyads, where forming each of the dyads includes forming a second layer comprising a barrier material over a first layer comprising a polymer or organic material. The method further includes wet coating a curable material over the second layer of at least one of the dyads and curing the curable material to form a passivation layer on the second layer. The barrier stack including the passivation layer has a water vapor transmission rate that is lower than a water vapor transmission rate of a barrier stack comprising the one or more dyads but not including the passivation layer. The method may further include forming the first layer on a fourth layer.

According to some embodiments, a barrier stack includes no more than 2 dyads, each dyad including a first layer comprising a polymer or organic material, and a second layer on the first layer and comprising a barrier material. The barrier stack further includes a passivation layer on the second layer of at least one of the dyads, where the passivation layer includes a wet coated and cured curable material. The barrier stack has a water vapor transmission rate on the order of 10⁻⁶ g/m²·day.

### BRIEF DESCRIPTION OF THE DRAWINGS

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention;

FIG. 3 is a schematic view of a barrier stack according to yet another embodiment of the present invention;

FIG. 4A is a transmission optical microscope image of the simplified barrier structure prepared according to Example 1 after 87 hours of accelerated aging in a 40° C. oven at 90% relative humidity;

FIG. 4B is a transmission optical microscope image of the simplified barrier structure prepared according to Comparative Example 1 after 87 hours of accelerated aging in a 40° C. oven at 90% relative humidity;

FIG. 5A is a transmission optical microscope image of the simplified barrier structure prepared according to Example 1 immediately after (i.e., t=0) coating and curing the top passivation layer; and

FIG. 5B is a transmission optical microscope image of the simplified barrier structure prepared according to Example 1 after 20 hours of accelerated aging in a 40° C. oven at 90% relative humidity.

### DETAILED DESCRIPTION

In embodiments of the present invention, a barrier stack includes a passivation layer (or defect-healing layer) on the oxide barrier layer. The passivation layer (or defect-healing layer) enables the reduction in the number of dyads needed to produce an “ultrabarrier” that is effective in protecting the underlying (or encapsulated) device from the permeation of moisture and oxygen, among other harmful elements. The passivation layer (or defect-healing layer) is wet coated on the oxide barrier layer, and “plugs” inherent defects in the layers, such as pinholes created during the deposition procedure (e.g., AC or DC sputtering). In particular, in wet coating the passivation layer (or defect-healing layer), the liquid of the layer seeps into the pinhole defects in the underlying oxide barrier layer, thereby blocking the pathway through the oxide barrier layer created by the pinhole defects, and preventing the ingress of moisture and oxygen through the pinholes to the underlying (or encapsulated) device. With the pathways created by the pinhole defects blocked by the passivation layer (or defect-healing layer), the resulting barrier stack has improved water vapor transmission properties, and fewer dyads are needed to provide a target water vapor transmission rate.

In some embodiments of the present invention, a barrier stack includes at least one dyad, and a top passivation layer. Each of the dyads includes a first layer that acts as a smoothing or planarization layer, and a second layer that acts as a barrier layer. The layers of the barrier stack can be directly deposited on a device to be encapsulated (or protected) by the barrier stack, or may be deposited on a separate substrate or support, and then laminated on the device. The first layer of the dyad includes a polymer or other organic material that serves as a planarization, decoupling and/or smoothing layer. Specifically, the first layer decreases surface roughness, and encapsulates surface defects, such as pits, scratches, digs and particles, thereby creating a planarized surface that is ideal for the subsequent deposition of additional layers. As used herein, the terms “first layer,” “smoothing layer,” “decoupling layer,” and “planarization layer” are used interchangeably, and all terms refer to the first layer, as now defined. The first layer can be deposited directly on the device to be encapsulated (e.g., an organic light emitting device), or may be deposited on a separate support. The first layer may be deposited on the device or substrate by any suitable deposition technique, some nonlimiting examples of which include vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The first layer can include any suitable material capable of acting as a planarization, decoupling and/or smoothing layer. Some nonlimiting examples of suitable such materials include organic polymers, inorganic polymers, organometallic polymers, hybrid organic/inorganic polymer systems, and silicates. In some embodiments, for example, the material of the first layer may be an acrylate-containing polymer, an alkylacrylate-containing polymer (including but not limited to methacrylate-containing polymers), or a silicon-based polymer.

The first layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the first layer. In some embodiments, for example, the first layer has a thickness of about 100 to 1000 nm.

The second layer of the dyad is the layer that operates as the barrier layer, preventing the permeation of damaging gases, liquids and chemicals to the encapsulated device. Indeed, as used herein, the terms “second layer” and “barrier layer” are used interchangeably. The second layer is deposited on the first layer, and deposition of the second layer may vary depending on the material used for the second layer. However, in general, any deposition technique and any deposition conditions can be used to deposit the second layer. For example, the second layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof.

In some embodiments, however, the second layer is deposited by AC or DC sputtering. For example, in some embodiments, the second layer is deposited by AC sputtering. The AC sputtering deposition technique offers the advantages of faster deposition, better layer properties, process stability, control, fewer particles and fewer arcs. The conditions of the AC sputtering deposition are not particularly limited, and as would be understood by those of ordinary skill in the art, the conditions will vary depending on the area of the target and the distance between the target and the substrate. In some exemplary embodiments, however, the AC sputtering conditions may include a power of about 3 to about 6 kW, for example about 4 kW, a pressure of about 2 to about 6 mTorr, for example about 4.4 mTorr, an Ar flow rate of about 80 to about 120 sccm, for example about 100 sccm, a target voltage of about 350 to about 550 V, for example about 480V, and a track speed of about 90 to about 200 cm.min, for example about 141 cm/min. Also, although the inert gas used in the AC sputtering process can be any suitable inert gas (such as helium, xenon, krypton, etc.), in some embodiments, the inert gas is argon (Ar).

The material of the second layer is not particularly limited, and may be any material suitable for substantially preventing or reducing the permeation of damaging gases, liquids and chemicals (e.g., oxygen and water vapor) to the encapsulated device. Some nonlimiting examples of suitable materials for the second layer include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Si, Zn, Sn or Ti.

The density and refractive index of the second layer is not particularly limited and will vary depending on the material of the layer. However, in some exemplary embodiments, the second layer may have a refractive index of about 1.6 or greater, e.g., 1.675. The thickness of the second layer is also not particularly limited. However, in some exemplary embodiments, the thickness is about 20 nm to about 100 nm, for example about 40 nm to about 70 nm. In some embodiments, for example, the thickness of the third layer is about 40 nm. As is known to those of ordinary skill in the art, thickness is dependent on density, and density is related to refractive index. See, e.g., Smith, et al., “Void formation during film growth: A molecular dynamics simulation study,” J. Appl. Phys., 79 (3), pgs. 1448-1457 (1996); Fabes, et al., “Porosity and composition effects in sol-gel derived interference filters,” Thin Solid Films, 254 (1995), pgs. 175-180; Jerman, et al., “Refractive index of this films of SiO2, ZrO2, and HfO2 as a function of the films' mass density,” Applied Optics, vol. 44, no. 15, pgs. 3006-3012 (2005); Mergel, et al., “Density and refractive index of TiO2 films prepared by reactive evaporation,” Thin Solid Films, 3171 (2000) 218-224; and Mergel, D., “Modeling TiO2 films of various densities as an effective optical medium,” Thin Solid Films, 397 (2001) 216-222, all of which are incorporated herein by reference. Also, the correlation between film density and barrier properties is described, e.g., in Yamada, et al., “The Properties of a New Transparent and Colorless Barrier Film,” Society of Vacuum Coaters, 505/856-7188, 38^{th} Annual Technical Conference Proceedings (1995) ISSN 0737-5921, the entire content of which is also incorporated herein by reference. Accordingly, those of ordinary skill in the art would be able to calculate the density of the second layer based on the refractive index and/or thickness information.

In the production of ultra-barriers, defects are introduced in the inorganic barrier layer (i.e., the second layer of the dyad) by the vacuum deposition process and the handling of the films. These defects are mainly created by particles falling on the substrate before and during the deposition process, as well as scratches and indentations created by handling (e.g., contact with rolls in web systems). The extrinsic defects created in the barrier layer during the production process are ingress paths for moisture and oxygen. These defects render the highly impermeable dense inorganic barrier layer (i.e., the second layer of the dyad) less effective as a permeation barrier against moisture and oxygen. The standard approach to minimize the impact of these defects is the use of multilayer barrier structures including a stack of several dyads. One of the functions of the organic layer (i.e., the first layer in the dyad) in such structures is to cover the particles on the substrate and landing on it during the barrier fabrication. Another function of the organic polymer layer (i.e., the first layer of the dyad) is to provide a smooth surface for the deposition of a high quality inorganic barrier layer (i.e., the second layer of the dyad). However, deposition of multiple dyads (as is standard protocol to minimize the impact of defects) increases the cost of fabrication of the final devices. In addition, when the number of dyads increases, the benefit of additional layers progressively diminishes because the additional fabrication rounds lead to more added defects.

According to embodiments of the present invention, the barrier stack includes a top passivation layer that includes a wet deposited curable material, and serves as a defect-healing or deformation sealing layer, plugging pinhole or other deformations in the second layer, which seals the pathways to the underlying device that those deformations would otherwise create for harmful gases and chemicals (e.g., water vapor and oxygen). As used herein, the term “curable material” refers to a material that is wet (i.e., liquid) when applied, but either dries or cures into a solid layer. As such, while the curable material may include a liquid polymeric material that solidifies upon cure (e.g., by thermal, UV or other curing mechanism), the curable material may also include a liquid slurry material that includes an inorganic substance (e.g., an inorganic oxide) suspended or dispersed in a liquid medium that forms a solid layer upon drying (i.e., upon removal of the liquid solvent from the slurry). Additionally, the curable material may include a “hybrid” material in which an inorganic material (e.g., an inorganic oxide) is suspended in a liquid polymeric material to form a hybrid polymeric slurry composition that forms a solid layer upon curing the polymeric material. In some embodiments, the top passivation layer may include two or more layers of the same or different curable materials. For example, in some embodiments, the passivation layer may include a first passivation layer including either a liquid polymeric curable material that cures into a solid film or an inorganic slurry including an inorganic material that forms a solid film after removal of the solvent in the slurry, and a second passivation layer also including either the liquid polymeric material or the slurry.

In some embodiments, the top passivation layer is deposited on the second layer of only the outermost dyad. In some embodiments, however, the top passivation layer may be deposited on each second layer of each dyad. In some embodiments, the top passivation layer may be deposited one or more second layers of the dyads in the barrier stack, so long as the top passivation layer is at least deposited on the second layer of the outermost dyad. The top passivation layer is deposited by a wet coating technique so that the material of the passivation layer seeps into pinhole or other deformations in the underlying barrier layer (or second layer) of the dyad, thereby generally sealing those deformations against the permeation of harmful chemicals, liquids and gases.

As discussed above, the curable material of the top passivation (or defect-healing) layer may be any liquid material that results in an inorganic film upon curing or drying (i.e., removal of a solvent). Nonlimiting examples of suitable such curable materials include liquid polymeric solutions that solidify upon curing using a known cure technique (e.g., thermal cure, UV, cure, etc.), inorganic slurry compositions including an inorganic material (e.g., an inorganic oxide) suspended or dispersed in a liquid solvent (e.g., water or an organic solvent such as an alcohol, ketone or acetate), and hybrid solutions including an inorganic material suspended or dispersed in a liquid polymeric solution that solidifies upon cure. Nonlimiting examples of suitable polymers for the liquid polymer solutions include organopolysiloxane polymers. In some embodiments, for example, the curable material in the liquid polymer solution may include an organopolysiloxane polymer produced by a sol-gel process. In some embodiments, the curable material includes an organosiloxane polymer produced by a water-borne sol-gel process. In some embodiments, the curable material includes a water-borne organofunctional silane sol-gel. Nonlimiting examples of suitable curable materials include SIVO 160 available from Evonik Industries (Germany), perhydropolysilazanes (such as those available from Clariant Advanced Materials GmbH, Germany), and the ORMOCER® line of products from Fraunhofer Polymer Surfaces Alliance (a.k.a, Fraunhofer POLO, Germany).

The inorganic material in the slurry compositions or hybrid systems may include any suitable inorganic material capable of plugging defects in the underlying barrier layer. For example, in some embodiments, the inorganic material may include an inorganic oxide. Some nonlimiting examples of suitable materials for the inorganic material include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Zn, Sn, Si or Ti. In some embodiments, the inorganic oxide may the same as or different from the inorganic oxide in the underlying barrier layer. In some embodiments, the inorganic oxide may be the same as the oxide in the underlying barrier film. Some nonlimiting examples of suitable inorganic materials include the AEROXIDE® (i.e., fumed alumina) and AEROSIL® (i.e., fumed silica) lines of products from Evonik Industries (Germany).

According to some embodiments, the slurry may include the inorganic oxide at a concentration of 10 wt % or less. For example, in some embodiments the slurry may include the inorganic oxide at a concentration of 5 wt % or less, or 1 wt % to 5 wt %. Additionally, in some embodiments, the inorganic oxide in the slurry has an average particle size of 200 nm or less, for example, less than 100 nm. In some embodiments, the inorganic oxide has an average particle size of 1 nm to 200 nm, or 1 nm to 100 nm. In some embodiments, for example, the inorganic oxide may have an average particle size of 1 nm to 70 nm, or 1 nm to 50 nm.

In the liquid polymeric solutions, the inorganic slurry compositions, and the hybrid systems, a solvent is used. For example, the solvent may be used to dilute the curable material (e.g., the liquid polymeric solution, inorganic slurry composition, or hybrid system) to different concentrations or viscosities in order to make application by wet coating easier, or to provide different concentrations of the curable material in the solution or composition depending on the number of localized defects in the underlying barrier layer, or the desired thickness or other properties of the resulting passivation layer. Any suitable solvent may be used for these purposes, and those of ordinary skill in the art would be capable of selecting a suitable solvent based on the desired properties of the resulting passivation layer. However, some nonlimiting examples of suitable solvents include alcohols, ketones, acetates and the like. For example, some nonlimiting examples of suitable alcohols include methanol, ethanol, propanol, isopropyl alcohol, and the like. A nonlimiting example of a suitable ketone is methyl isobutyl ketone (MIBK), and a nonlimiting example of a suitable acetate is propylene glycol monomethyl ether acetate (PGMEA). However, in embodiments in which the barrier stack is to be deposited directly on the device to be protected (e.g., an OLED), it may be desirable to use a non-water solvent in order to prevent any water from the initial application of the curable material from seeping through the localized defects in the underlying barrier layer before the layer has been dried to remove the water.

The amount of polymer and/or inorganic material in the curable material is not particularly limited. Indeed, the amount of polymer and/or inorganic material in the curable material should be sufficient to plug certain defects in the underlying barrier layer, but not so high that the curable material cannot be effectively deposited by a wet coating technique. In some embodiments, for example, the curable material should include enough of the polymer and/or inorganic material to plug defects that are less than a micron in size. In some embodiments, the curable material may contain the polymer and/or inorganic oxide in a solids content of 1% to 10%, for example, 1% to 5%. When the curable material includes the polymer and/or inorganic material in an amount within either of these ranges, the resulting top passivation layer effectively plugs enough defects in the underlying barrier layer to register a measurable improvement in the water vapor transmission rate of the overall barrier stack. In particular, in some embodiments, the barrier stack without the top passivation layer registers a water vapor transmission rate that is measurably greater than the water vapor transmission rate of the same barrier stack including the top passivation layer. For example, in some embodiments, the inclusion of the top passivation layer according to embodiments of the present invention can improve the water vapor transmission rate of the barrier stack by up to a full order of magnitude. Specifically, in some embodiments, the barrier stack without the top passivation layer may have a water vapor transmission rate on the order of 10⁻⁵ g/m²·day, and a water vapor transmission rate of 10⁻⁶ g/m²·day with the top passivation layer. Indeed, the top passivation layer according to embodiments of the present invention is particularly effective at lowering the water vapor transmission rate of the barrier stack when the underlying barrier layer has a density of localized defects of 1/cm² and a water vapor transmission rate on the order of 10⁻⁵ g/m²·day.

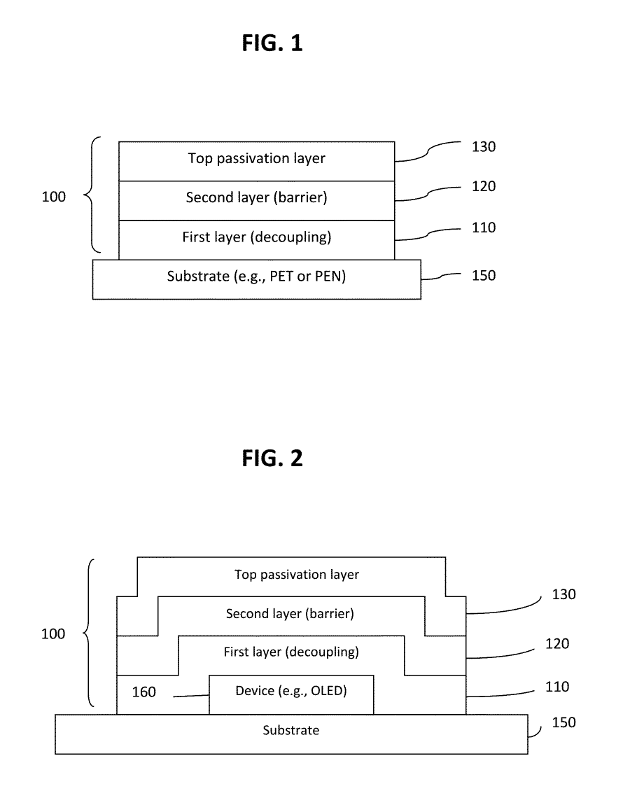

Exemplary embodiments of a barrier stack according to the present invention are illustrated in FIGS. 1 and 2. The barrier stack 100 depicted in FIG. 1 includes a first layer 110 which includes a decoupling layer or smoothing layer (i.e., the first layer discussed above), a second layer 120 which includes a barrier layer (i.e., the second layer discussed above), and a top passivation layer 130 which includes the curable material discussed above. In FIG. 1, the barrier stack 100 is deposited on a substrate 150, for example any common substrate, nonlimiting examples of which may include polyethylene terephthalate (PET), polyethylene naphthalate (PEN), polycarbonate, polyimide, and polyetherether ketone (PEEK). However, in FIG. 2, the barrier stack 100 is deposited directly on the device 160, e.g., an organic light emitting device.

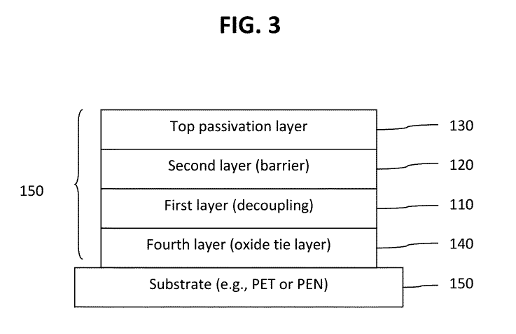

In addition to the first and second layers 110 and 120, respectively, making up a dyad, and the top passivation layer 130, some exemplary embodiments of the barrier stack 100 can include a fourth layer 140 between the first layer 110 and the substrate 150 or the device 160 to be encapsulated. Although the inventive barrier stacks are discussed herein and depicted in the accompanying drawings as including first and second layers 110 and 120, respectively, of a dyad, a top passivation layer 130, and a fourth layer 140, it is understood that these layers may be deposited on the substrate 150 or the device 160 in any order so long as the top passivation layer 130 is on at least the second layer of the outermost dyad, and the identification of the first, second and fourth layers as first, second, and fourth, respectively, does not mean that these layers must be deposited in that order. Indeed, as discussed here, and depicted in FIG. 3, in some embodiments, the fourth layer 140 is deposited on the substrate 150 or device 140 prior to deposition of the first layer 110.

The fourth layer 140 acts as a tie layer, improving adhesion between the layers of the barrier stack 100 and the substrate 150 or the device 160 to be encapsulated. The material of the fourth layer 140 is not particularly limited, and can include the materials described above with respect to the second layer. Also, the material of the fourth layer may be the same as or different from the material of the second layer. The materials of the second layer are described in detail above.

Additionally, the fourth layer may be deposited on the substrate or the device to be encapsulated by any suitable technique, including, but not limited to the techniques described above with respect to the second layer. In some embodiments, for example, the fourth layer may be deposited by AC or DC sputtering under conditions similar to those described above for the second layer. Also, the thickness of the deposited fourth layer is not particularly limited, and can be any thickness suitable to effect good adhesion between the first layer of the barrier stack and the substrate or device to be encapsulated. In some embodiments, for example, the fourth (tie) layer can have a thickness of about 20 nm to about 60 nm, for example, about 40 nm.

An exemplary embodiment of a barrier stack 100 according to the present invention including a fourth layer 140 is depicted in FIG. 3. The barrier stack 100 depicted in FIG. 3 includes a first layer 110 which includes a decoupling layer, a fourth layer 140 which includes an oxide tie layer, a second layer 120 which includes a barrier layer, and a top passivation layer 130 which includes the curable material discussed above. In FIG. 3, the barrier stack 100 is deposited on a substrate 150, for example any common substrate, nonlimiting examples of which may include PET, PEN, polycarbonate, polyimide, and polyetherether ketone (PEEK). However, it is understood that the barrier stack 100 can alternatively be deposited directly on the device 160, e.g., an organic light emitting device, as depicted in FIG. 2 with respect to the embodiments excluding the fourth layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a first layer 110 on the substrate. The first layer 110 is as described above and acts as a decoupling/smoothing/planarization layer. As also discussed above, the first layer 110 may be deposited on the device 160 or substrate 150 by any suitable deposition technique, including, but not limited to, vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The method further includes depositing a second layer 120 on the surface of the first layer 110. The second layer 120 is as described above and acts as the barrier layer of the barrier stack, serving to substantially prevent or substantially reduce the permeation of damaging gases, liquids and chemicals to the underlying device. The deposition of the second layer 120 may vary depending on the material used for the second layer. However, in general, any deposition technique and any deposition conditions can be used to deposit the second layer. For example, the second layer 120 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof. In some embodiments, however, the second layer 120 is deposited by AC or DC sputtering, for example pulsed AC or pulsed DC sputtering. While any suitable conditions for deposition can be employed, some suitable conditions are described above.

Additionally, the method includes depositing a top passivation layer 130 on the second layer 120. As discussed above, the top passivation layer plugs defects in the second layer that are created during deposition and handling of the second layer 120. The top passivation layer 130 may be deposited by any suitable wet coating technique. Nonlimiting examples of suitable wet coating techniques include dip coating, spray coating, flow coating, spin coating, bar coating, printing techniques (e.g. ink jet printing), roll coating, etc. After coating the curable material of the top passivation layer 130 on the second layer 120, the curable material is dried and/or cured to form the top passivation layer, which is a solid (e.g., polymeric or inorganic oxide-based) film. Depending on the curable material used for the top passivation layer 130, the layer may then be either dried to remove solvent (when the curable material is a slurry) or cured to solidify the film (when the curable material is a polymeric solution). As discussed above, in some embodiments, the top passivation layer may include a first layer deposited using a slurry, and a second layer deposited using a polymeric solution. In these embodiments, the first slurry layer may be dried after deposition and the second polymer layer may be cured after deposition. However, in some of these embodiments, the cure conditions of the second polymer layer may be sufficient to simultaneously drive off the solvent from the first slurry layer and cure the second polymer layer.

In some embodiments, the method further includes depositing a fourth layer 140 between the substrate 150 (or the device 160 to be encapsulated) and the first layer 110. The fourth layer 140 is as described above and acts as a tie layer for improving adhesion between the substrate or device and the first layer 110 of the barrier stack 100. The fourth layer 140 may be deposited by any suitable technique, as discussed above. For example, as also discussed above, the fourth layer 140 may be deposited on the substrate 150 (or the device 160 to be encapsulated) by AC or DC sputtering, e.g., pulsed AC or pulsed DC sputtering.

The following Examples are provided for illustrative purposes only, and do not limit the present disclosure. In the Examples (except where indicated to the contrary), each of the top passivation layers were deposited on an underlying, simplified test barrier stack in which a 70 nm thick Ca layer on a glass substrate was coated with a 120 nm Al₂O₃ layer deposited by pulsed AC or DC sputtering. The Ca layer in these examples is used as a proxy for an OLED device, as calcium layers are highly reactive with water, and enable easy visualization of localized oxidation by changes in transparency (i.e., oxidation of metallic Ca to calcium oxide, which is more transparent than the metallic Ca). The water vapor transmission of each of the samples was assessed by exposing each sample to accelerated aging conditions, i.e., each sample was place in a 40° C. oven at 90% relative humidity for more than 1000 hours. The change in water vapor transmission was recorded periodically, and the morphology of the samples was assessed by observation through a transmission optical microscope.

The simplified Ca test stack used in the Examples is not an ultra-barrier, and is more sensitive to defects on the surface of the oxide barrier layer. For purposes of these tests, particles larger than about 120 nm were not covered by the sputtered oxide barrier layer, and smaller particles created significant defects in the deposited barrier layer. As this structure is overly sensitive, it allows easy assessment of the efficacy of the top passivation (or defect-healing) layer.

Additionally, relatively mild accelerated aging conditions were used in order to slow down the oxidation of the underlying Ca film, thereby allowing for repeated observation of how oxidation was proceeding.

### EXAMPLE 1

A simplified test barrier stack was prepared as discussed above, and a top passivation layer was deposited on the oxide barrier layer. The top passivation layer was prepared by wet coating a 5% solution of SIVO 160 (a water-borne siloxane produced by sol-gel available from Evonik Industries (Germany)) in deionized water, followed by cure. The top passivation layer was cured by thermal cure at a temperature greater than 20° C. for several minutes. However, as would be understood by those of ordinary skill in the art, when deposited on a plastic or polymeric substrate (e.g., PET or PEN), the temperature and length of time of the thermal cure will be lower. The top passivation layer had a thickness of about 100 nm.

### COMPARATIVE EXAMPLE 1

The simplified test barrier stack was prepared as discussed above, and used as a control without the deposition of a top passivation layer.

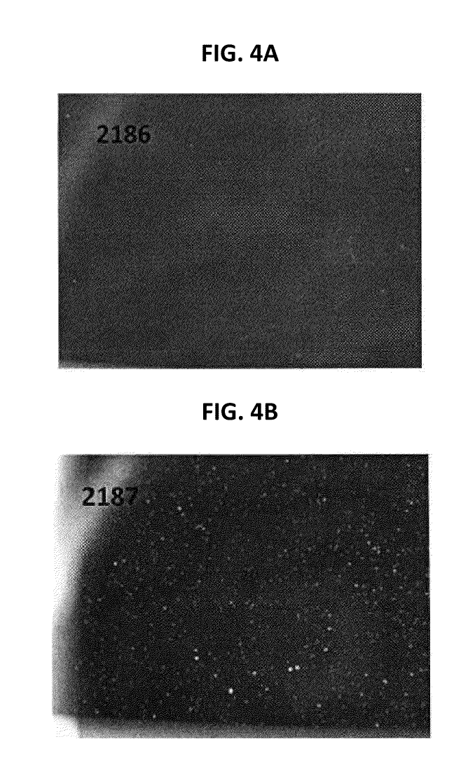

FIG. 4A is a transmission optical microscope image of the structure of Example 1 after 87 hours of accelerated aging, and FIG. 4B is a transmission optical microscope image of the structure of Comparative Example 1 after 87 hours of accelerated aging. As can be seen in FIG. 4A, very few pinholes corresponding to localized regions of oxidized Ca can be seen in the samples including the top passivation layer. In contrast, as can be seen in FIG. 4B, a large population of pinholes can be seen in the samples without the top passivation layer, indicating that the metallic Ca film rapidly oxidized from moisture penetrating through defects in the barrier layer.

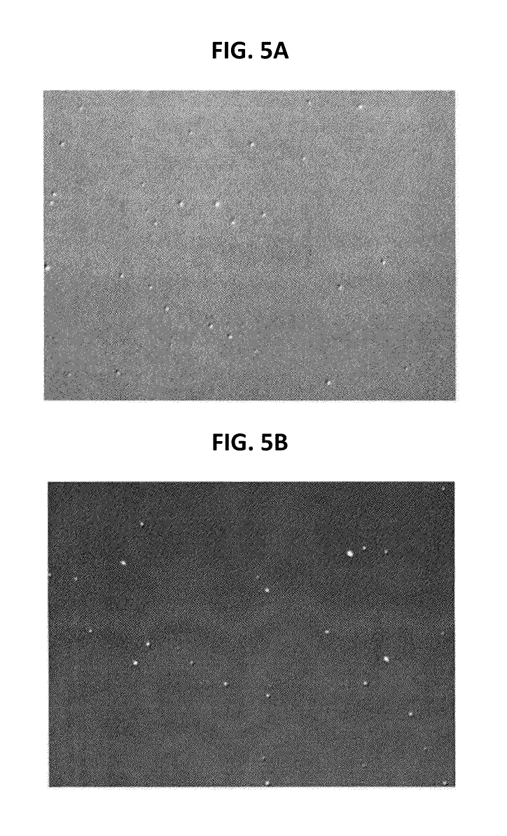

Additionally, FIG. 5A is a transmission optical microscope image of the structure according to Example 1 (including the top passivation layer) immediately after deposition and cure (i.e., t=0), and FIG. 5B is a transmission optical microscope image of the same structure after 20 hours of accelerated aging. As can be seen in FIG. 5A, some pinhole defects appear after coating and cure of the siloxane passivation layer. These defects are caused by the initial exposure to the water in the coating liquid (i.e., the diluent solvent). However, as can be seen in FIG. 5B, the size and density of the defects appearing after coating do not change upon further exposure to accelerated aging conditions. This proves that the moisture ingress path originally created by the initial exposure to water is sealed by the passivation layer. It is also worth noting that while the simplified barrier stack structure used in these Examples helped prove the existence of a defect and the sealing ability of the top passivation layer, the defects created upon initial application of the top passivation layer would not be formed in a typical barrier stack including a polymer decoupling layer. In particular, in such an ultra-barrier construction (including the polymer decoupling layer), there is no direct contact between the penetrating moisture and the underlying device (or Ca layer in the test sample), and because the penetrating moisture would not be enough the saturate the polymer decoupling layer.

As discussed above, according to embodiments of the present invention, a barrier stack includes at least one dyad and a top passivation layer on the barrier layer of the dyad. The top passivation layer increases the reliability of the barrier created by barrier stack, and enables a reduction in the number of dyads needed to create an effective barrier. For example, where other barrier stacks not including a top passivation layer may require 3 or more dyads to create a barrier with a sufficient water vapor transmission rate (e.g., a water vapor transmission rate on the order of 10⁻⁴ b/m²·day), barrier stacks according to embodiments of the present invention can achieve the same or better water vapor transmission rate (e.g., a water vapor transmission rate on the order of 10⁻⁴ b/m²·day or better, for example, 10⁻⁶ b/m²·day or better) with fewer than 3 dyads, for example 1 or 2 dyads. For example, in some embodiments, the barrier stack includes no more than 2 dyads. The barrier stacks according to embodiments of the present invention can be used for either direct thin film encapsulation of sensitive devices (such as, e.g., OLEDs), or for ultra-barrier laminates deposited on a plastic foil to be used for substrate or encapsulation by lamination of the sensitive device.

While certain exemplary embodiments of the present invention have been illustrated and described, it is understood by those of ordinary skill in the art that certain modifications and changes can be made to the described embodiments without departing from the spirit and scope of the present invention.

What is claimed is:

1. A barrier stack, comprising:
one or more dyads, each dyad comprising a first layer comprising a polymer or organic material, and a second layer on the first layer and comprising a barrier material;
a passivation layer on the second layer of one or more of the one or more dyads, the passivation layer comprising a wet coated and cured curable material, wherein the barrier stack including the passivation layer has a water vapor transmission rate that is lower than a water vapor transmission rate of a barrier stack comprising the one or more dyads but not including the passivation layer.

2. The barrier stack of claim 1, further comprising a fourth layer, wherein the first layer is on the fourth layer.

3. The barrier stack of claim 1, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

4. The barrier stack of claim 1, wherein the barrier material of the second layer is selected from the group consisting of metals, metal oxides, metal nitrides, metal oxynitrides, metal carbides, metal oxyborides, Al, Zr, Zn, Sn, Ti, and combinations thereof.

5. The barrier stack of claim 1, wherein the curable material comprises a liquid polymer solution, an inorganic slurry composition, or a hybrid system comprising an inorganic material and a liquid polymer solution.

6. The barrier stack of claim 5, wherein the liquid polymer solution comprises an organopolysiloxane polymer and a solvent.

7. The barrier stack of claim 5, wherein the liquid polymer solution comprises a water borne polysiloxane polymer prepared by a sol-gel process, and a solvent.

8. The barrier stack of claim 5, wherein the inorganic slurry composition comprises an inorganic oxide dispersed in a solvent.

9. The barrier stack of claim 5, wherein the liquid polymer solution comprises a solvent.

10. A method of making a barrier stack, comprising:
forming one or more dyads, wherein forming each of the dyads comprises forming a second layer comprising a barrier material over a first layer comprising a polymer or organic material;
wet coating a curable material over the second layer of one or more of the one or more dyads;
curing the curable material to form a passivation layer on the second layer;
wherein the barrier stack including the passivation layer has a water vapor transmission rate that is lower than a water vapor transmission rate of a barrier stack comprising the one or more dyads but not including the passivation layer.

11. The method of claim 10, further comprising forming the first layer on a fourth layer.

12. The method of claim 10, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

13. The method of claim 10, wherein the barrier material of the second layer is selected from the group consisting of metals, metal oxides, metal nitrides, metal oxynitrides, metal carbides, metal oxyborides, Al, Zr, Zn, Sn, Ti, and combinations thereof.

14. The method of claim 10, wherein the curable material comprises a liquid polymer solution, an inorganic slurry composition, or a hybrid system comprising an inorganic material and a liquid polymer solution.

15. The method of claim 14, wherein the liquid polymer solution comprises an organopolysiloxane polymer and a solvent.

16. The method of claim 14, wherein the liquid polymer solution comprises a water borne polysiloxane polymer prepared by a sol-gel process, and a solvent.

17. The method of claim 14, wherein the inorganic slurry composition comprises an inorganic oxide dispersed in a solvent.

18. The method of claim 14, wherein the liquid polymer solution comprises a solvent.

19. A barrier stack, comprising:
no more than 2 dyads, each dyad comprising a first layer comprising a polymer or organic material, and a second layer on the first layer and comprising a barrier material;
a passivation layer on the second layer of one or more of the one or more dyads, the passivation layer comprising a wet coated and cured curable material, wherein the barrier stack has a water vapor transmission rate on the order of 10⁻⁶ g/m²·day.
